(19) United States
(12) Patent Application Publication
(10) Pub. No.: US 2012/0235294 A1
(43) Pub. Date: Sep. 20, 2012

(54) NOVEL WATER-COOLING RADIATOR OF THYRISTOR

(76) Inventors: Guang fu Tang, Beijing (CN); Jian hui Zhow, Beijing (CN); Xiao Guang Wei, Beijing (CN); Kun Peng Zha, Beijing (CN)

(21) Appl. No.: 13/255,502

(22) PCT Filed: Jun. 16, 2011
(86) PCT No.: PCT/CN2011/001004

§ 371 Date: Sep. 8, 2011

(30) Foreign Application Priority Data
Aug. 27, 2010 (CN) 20100264133.1

(51) Int. Cl. H01L 23/473

(52) U.S. Cl. 257/714; 257/E23.098

(57) ABSTRACT

The present invention relates to electric equipment field, and relates particularly to a novel water-cooling radiator of thyristor. This radiator flow channel design adopted helical flow channel combined with cellular fin structure. There are some advantages of this design: the flow resistance and thermal resistance is smaller, radiator surface temperature is homogeneous, heat change of inner water is enough, there are no flow dead zone and partial heat accumulation, the thermal resistance and the flow resistance are all adjusted according to design requirements by changing the circle number of helical flow channel and the layer number of cellular fin.

### FIELD OF THE INVENTION

The present invention relates to electric equipment field, and relates particularly to a novel water-cooling radiator of thyristor.

### BACKGROUND OF THE INVENTION

At present, there is no similar technology and invention at home and abroad. There are two typical flow channel designs the traditional 6 inch thyristor water-cooling radiator: 1. the flow channel adopts the Archimedes' spiral design, and increase the bursal rays to enhance convective heat transfer. 2. The flow channel adopts large cavum design, and lay several floors cellular to be a three-dimensional flow channel to enhance heat transfer.

Different flow channel design and inner fin distribution influences greatly to the flow resistance and thermal resistance of the radiator. The design 1 radiator often has good thermal performance, and also good surface temperature distribution which can fulfill the surface temperature requirements of the radiator for thyristor elements. However, the resistance is much greater because of longer flow. Therefore, the total pressure drop of the system is much greater, which can cause water leak. This radiator is suitable for the smaller flow. Under great flow condition, it needs very high pumping pressure that the flow water passes through the radiator. The design 2 radiator often has little flow resistance because of the inner complexity and three-dimension structure. But it has badly thermal resistance performance because the flow velocity is fast and the heat change is not enough. There are four flow bead zones in the quadrate channel cavum, which exacerbates partial convective heat transfer. The surface temperature of the radiator beside the outlet is much higher; it causes the bad surface temperature homogeneity. This radiator is suitable for the larger flow. Under smaller flow condition, the partial convective heat change is bad because the flow velocity is too slow through the radiator.

### SUMMARY OF THE INVENTION

This present invention provided a novel water-cooling radiator of thyristor, as FIG. 1 shown. This radiator flow channel design adopted helical flow channel combined with cellular fin structure. There are some advantages of this design: the flow resistance and thermal resistance is smaller, radiator surface temperature is homogeneous, heat change of inner water is enough, there are no flow dead zone and partial heat accumulation, the thermal resistance and the flow resistance are all adjusted according to design requirements by changing the circle number of helical flow channel and the layer number of cellular fin.

With this aim in view, the present invention resides in that a novel water-cooling radiator of thyristor, it includes helical flow channel and cellular fin, said cellular fins are distributed in the helical flow channel regularly, the cooling water flows in the channels to change heat.

Wherein said helical flow channel and cellular fin is combined together to form a novel channel, the cooling water enters into the radiator from one side of the helical channel, passes through the multi-floor cellular fins to shunt and change heat, then influx together in the center zone of the helical flow to cool center of the thyristor whose temperature is highest, and then the water gets out from another side of the helical channel.

Wherein the circle number of said helical flow channel and the layer number of said cellular fin are both adjusted according to the heat transfer requirement and the flow rate, the circle number of the helical flow channel and the layer number of the cellular fin can be reduced when the flow resistance is great, while the number can be increased when flow resistance is small.

Wherein said layer number of said cellular fin is 1˜5 layers and its thickness is 1-10 mm.

There are some advantages of the present invention compared with the prior module in the following:

1. It has smaller flow resistance and thermal resistance, good surface temperature homogeneity.

2. It has wide applicability, can fulfill different heat transfer and flow rate requirements.

### BRIEF DESCRIPTION OF THE DRAWINGS

Currently preferred embodiments of the invention will now be described with reference to the following attached drawings in which:

FIG. 1 is structure schematic diagram of the flow channel of the present invention water-cooling radiator of thyristor , in these figures:

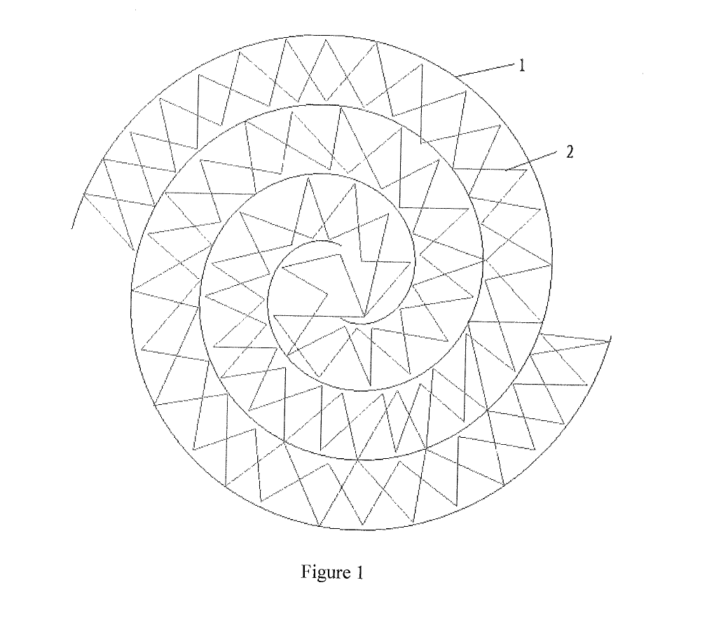

1-helical flow channel, 2-cellular fin;

### DETAILED DESCRIPTION OF EMBODIMENTS

The detail of the embodiments is described as below incorporated with the figures by way of cross-reference. This invention mainly changed the design of flow channel design of the 6 inches thyristor valve water-cooling radiator. The radiator mainly included helical flow channel 1 and cellular fin 2 two parts as figure land 2 shown. The cooling water enters into the radiator from one side of the helical channel, passes through the multi-floor cellular fins to shunt and change heat, then influx together in the center zone of the helical flow to cool center of the thyristor whose temperature is highest, and then the water gets out from another side of the helical channel. To optimize the heat transfer, the angle between two cellular fin ends designed 30°-90°. This assignment of flow channel and fins played the advantages of Archimedes' spiral flow channel and multi-layer cellular cavum. 1. The water was limited by the helical flow channel, and the water “short circuit” won't happen, the heat enough changed. 2. The water in the channel avoided the simplex helical flow; it carried out the three-dimensional flow through the multi-layer cellular. It is that water not only flows along the helical direction and also “climbs” up and down along cellular fins, which enhanced the convection heat change. 3. The design made full use of the advantages of the small thermal resistance of helical channel and small flow resistance of cellular resistance, which can fulfill different thermal and flow resistance requirements by adjusting the circle number of channel and density of the cellular fin. This radiator can be applied widely. 4. The radiator surface temperature is homogeneous because it adopts helical flow channel totally, which can fulfill thyristor strict requirements to radiator.

At last, the detail embodiment is one example of the invention but not the only one, so the person in this field must be understand that all the alternatives and other equal and/or similar examples are all within the range of the invention and they are all consistent with the spirits of this invention, are all protected by our claims.

1. A novel water-cooling radiator of thyristor is characterized by which includes helical flow channel and cellular fin, said cellular fins are distributed in the helical flow channel regularly, the cooling water flows in the channels to change heat.

2. A novel water-cooling radiator of thyristor according to claim 1, wherein said helical flow channel and cellular fin is combined together to form a novel channel radiator, the cooling water enters into the radiator from one side of the helical channel, passes through the multi-floor cellular fins to shunt and change heat, then influx together in the center zone of the helical flow to cool center of the thyristor whose temperature is highest, and then the water gets out from another side of the helical channel.

3. A novel water-cooling radiator of thyristor according to claim 1 and/or 2, wherein the circle number of said helical flow channel and the layer number of said cellular fin are both adjusted according to the heat transfer requirement and the flow rate, the circle number of the helical flow channel and the layer number of the cellular fin can be reduced when the flow resistance is great, while the number can be increased when flow resistance is small.

4. A novel water-cooling radiator of thyristor according to claim 3, wherein said layer number of said cellular fin is 1˜5 layers and its thickness is 1-10 mm.
